(19) United States
(12) Patent Application Publication
(10) Pub. No.: US 2022/0250113 A1
(43) Pub. Date: Aug. 11, 2022

(54) METHOD AND DEVICE FOR PRODUCING ELECTRICAL COMPONENTS ON A FLEXIBLE SUBSTRATE

(71) Applicant: Value & Intellectual Properties Management GMBH, Bruckmühl (DE)

(72) Inventors: Kai Bär, Bad Aibling (DE); Andreas Geitner, Rottach-Egern (DE); Michael Dienz, Neuss (DE)

(73) Assignee: Value & Intellectual Properties Management GMBH, Bruckmühl (DE)

(21) Appl. No.: 17/615,701

(22) PCT Filed: May 20, 2020
(86) PCT No.: PCT/EP2020/064055

§ 371 Date: Dec. 1, 2021

(30) Foreign Application Priority Data
Jun. 3, 2019 (DE) 10 2019 114 806.5

(51) Int. Cl. B05D 3/02; H01M 4/04; H01M 4/88; B05D 1/42; H05K 3/12

(52) U.S. Cl. CPC B05D 3/0263; H01M 4/0404; H05K 3/1283; H01M 4/0471; B05D 1/42; H01M 4/8885

(57) ABSTRACT

The invention relates to a method for producing electrical or electronic components or circuits on a flexible, flat or three-dimensional substrate via the application of a liquid or paste-like starting material for a structured or unstructured electrical or electronic functional layer, and subsequent drying, sintering and/or curing of the starting material on the substrate, wherein the step of drying, sintering and/or curing involves a short surface-application of the coated substrate with radiation in the near-infrared range, with an amplitude maximum in a wavelength range between 800 and 1500 nm and with a power density on the surface of the substrate between 50 kW/m² and 1000 kW/m².

The invention relates to a method for producing electrical or electronic components or circuits on a flexible, flat or three-dimensional substrate via the application of a liquid or paste-like starting material for a structured or unstructured electrical or electronic functional layer, and subsequent drying, sintering and/or curing the starting material on the substrate, as well as an arrangement for performing this method.

The production of functional layers, which includes sintering or curing an originally liquid or paste-like starting material, on components of electrical devices, energy storage systems or in electronic components or assemblies has long been part of the state of the art.

Due to the dramatically increasing technical and economical importance of modern battery technologies, on the one hand, and the equally fast spread of printed electronic circuits of this kind (so-called “printed electronics”), such methods gain growing technical and commercial importance. An increasingly important factor is in this case the use of substrate materials that are preferably easily available and cost-efficient and moreover recyclable, and on the other hand a manner of proceeding adapted to these novel substrate materials having a preferably high yield of high-quality final products.

In novel battery constructions required, for example, for electromotive mobility and, as a perspective also for high-performance storage systems in the field of energy generation, polymer films such as on the basis of PE, PVC, PET or PP or else of paper, are used apart from metallic substrate films. Furthermore, efforts have been made to use water-soluble coatings to the widest possible extent for environmental and industrial safety reasons. Similar configurations have been proposed for electrodes of fuel cells such as might be found in the future in vehicles driven by fuel cells.

In drying or curing the coatings, the temperature sensitivity of the substrate material must be taken into account, on the one hand, and efforts must be made to obtain a qualitatively perfect coating (without defects caused by drying) at a throughput speed through a corresponding drying plant that is as high as possible. There is no need to say that also the production and operation costs for the drying plants play a significant role for the costs of the final products—which should become lower and lower as they are increasingly used on a mass scale. Known drying plants of the tunnel furnace type satisfy these requirements only in a limited manner and need much space and are expensive in production and operation.

The invention is therefore based on the task to provide an improved method of the generic kind and a corresponding arrangement fulfilling the above requirements.

This task is solved by a method having the features of claim 1, as well as an arrangement having the features of claim 11. Appropriate further developments of the idea of the invention are the subject of the respective dependent claims.

The invention includes the idea of providing the energy required for sintering and/or curing the starting material on the substrate which is of low temperature stability at least because of its thickness, but often also because of the material, in such a manner that it develops its effect substantially within the coating, and the thermal total load of the substrate remains as low as possible (over the time range of the drying process). For typical coating materials, in particular those on the basis of water, radiation in the near-infrared range has proven to be successful, the amplitude maximum of which is in the wavelength range between 800 nm and 1,500 nm. This radiation is implemented in mostly water-based (but also solvent-containing) solutions, emulsions and pastes in a particularly effective manner.

Furthermore, the invention includes the idea of letting this radiation act with such an elevated power density that the aspired sintering and/or curing in the substrate can take place in such a short time that the energy amount transmitted to the substrate and thus its thermal total load remains limited. Depending on the specific case of application, substrate and coating, energy densities in the range between 50 kW/m² and 1,000 kW/m², in particular of 120 kW/m² at 1,000 kW/m² on the coating surface seem to be suitable from today's point of view.

According to the findings of the inventors, the exposure time of the near-infrared radiation may be limited to the range between 1 s and 3 s, in particular between 2 s and 20 s for many of the current applications. As a matter of fact, the specific treatment duration depends on the thickness and nature of the coating and of the specifically chosen power density.

In applications which are particularly promising from today's point of view, the substrate is a temperature-sensitive substrate, such as a polymer film or paper, and the power density and the exposure time of the near-infrared radiation are set such that the temperature does not rise above a material-critical temperature, in particular not above a temperature in the range between 100° C. and 200° C. The specific value of the limit temperature of course depends on the material, and the setting of the power density for maintaining this limit value and the throughput speed of the substrate through the drying plant has to be determined by the expert by means of a restricted number of simple trials.

The method in this configuration has a potential in the further development of “printed electronics” as an application range which is rich in perspectives. In this case, liquid starting material is selectively or punctually applied onto the substrate by a printing process. This is made in an especially precise, fast and efficient manner by means of an inkjet printing process. The power density and exposure time of the near-infrared radiation are set such that within the selective coating, a temperature above a material-specific sintering or curing temperature, in particular above a temperature in the range between 50 and 200° C. is achieved for a short time.

In a further potentially important application, a paste-like starting material is applied onto the substrate over the whole surface, in particular by a roller or blade application process and is subsequently structured, if necessary (e.g. by etching processes of by means of laser). The power density and exposure time of the near-infrared radiation, here as well, are set such that within the selective coating, a temperature above a material-specific sintering or curing temperature is achieved for a short time. This configuration might acquire particular importance in the field of production of battery electrodes for electromotive mobility and energy technology, as well as of fuel cell electrodes.

A special proposed methodological proceeding in this field is based on the fact that, as a substrate, a polymer film having a thickness in the range between 75 μm and 200 μm or a metal film in the range between 3 μm and 10 μm, and as the coating, a viscous paste on the basis of water or based on an organic solvent is used, which has an initial thickness in the range between 10 and 1,000 μm and a solid content in the range between 40% and 80%. In this case, it is intended to use near-infrared radiation having a power density in the range between 50 and 200, in particular 70 and 150 kW/m² for the drying, sintering and/or curing. In this application, which can be referred to as a “thick film application”, precise control of the radiation impact as a function of the parameters of the substrate and the coating, and also in temporal respect is preferred. In particular in the starting and ending portion of an elongate, flat substrate, temporal control is of significant importance for the quality of the final product and the yield of the process.

In a further application which can be referred to as a “thin film application” and is important e.g. in “printed electronics”, the coating merely has a thickness in the range between approximately 1 and 20 μm and is applied onto the substrate by means of printing or spraying (“jet technology”). In this application, it is possible to work with fixedly set power densities of the NIR radiation, if necessary, and these may exceed the values mentioned above.

In further configurations of the method according to the invention it is provided for the contacting with near-infrared radiation to be performed within a NIR irradiation zone at a predetermined profile of non-constant power density. In this case, the power density profile may in particular be settable in response to material characteristics of the substrate and/or the starting material.

By such methodological proceedings, specific requirements of certain functional layers and also particularly temperature-sensitive substrates may be taken into account in a differentiated manner. Pre-warming phases and temperature maintaining phases may thus be set before or after a main drying phase at high power density.

Incidentally, a temperature maintaining zone may also be realized independently from the use of the near-infrared radiation in a downstream plant component, in particular a hot air dryer.

In a further potentially advantageous methodological proceeding, the contacting with near-infrared radiation is performed from both surfaces of the substrate. This methodological proceeding seems to be suitable when relatively temperature-stable substrates (such as metal films) are used. If it is intended to be used for products having a temperature-sensitive substrate, in particular the setting of various power densities on the surface of the coating, on the one hand, and on the surface (rear side) of the substrate, on the other hand, seems to be reasonable.

In a further special methodological proceeding, the contacting with near-infrared radiation is linked to the contacting with an air flow at least on one surface of the substrate. Such a hot air flow allows in particular evaporated liquid constituents of the coating to be discharged in an easy and targeted manner (e.g. into appropriate filters). On the other hand, excessive heating of the substrate material may also be prevented when high power densities need to act for a relatively long time. This may be necessary for warming up a relatively thick or materially demanding coating sufficiently.

It can be provided especially for supplying warm air into the irradiation zone and/or for supplying hot air in an optionally provided hot air dryer respectively onto both of the surfaces of the substrate and being in particular settable.

Device aspects of the present invention result to a large extent from the method aspects explained above. Therefore, repeating of the explanations above under device considerations may be omitted to a large extent.

According to the above, the arrangement according to the invention comprises at least conveyance means for conveying the flexible flat substrate through the arrangement, coating means for coating the flat substrate with the starting material, in particular during conveyance of the substrate, and means for drying, sintering and/or curing the starting material layer on the substrate, in particular during conveyance of the substrate, which include at least one radiation source for radiation in the range of near infrared, the amplitude maximum of which is in the wavelength range between 800 nm and 1,500 nm, and which is made, configured or settable such that its power density on the surface of the substrate is in the range between 50 kW/m² and 1,000 kW/m².

The means for drying, sintering and/or curing in particular include a plurality of NIR radiation sources, which are arranged and/or controllable in a NIR irradiation zone such that, within the irradiation zone, a predetermined profile of non-constant power density is producible. This can in particular be configured such that the NIR radiators have different distances and different reflector geometries over the length of the irradiation zone and/or are placed at different distances over the surface of the coated substrate or they are radiation sources of different power.

The mentioned profile of non-constant power density over the length of the irradiation zone may also be controllable in that, for example, means for the power control of some or all of the NIR radiation sources or mechanical setting means for variably setting the height of the radiation sources are provided above the substrate. In this manner, the irradiation zone may in particular be configured flexibly into a pre-warming range and a main drying range and/or a main drying range and a temperature maintaining range.

For realizing the mentioned treatment temperature maintaining zone, a separate treatment portion may also be provided in the drying arrangement, which is in particular constructed as a hot air dryer or as a tunnel furnace.

Furthermore, the NIR irradiation source may have means assigned for supplying an air flow, thus in particular one or more ventilators having associated air conduction means. In a further configuration these may be configured such that the air flow, after having flown across the surface of the coating, gets into a filtering device for filtering out harmful solvent components of the coating and/or gets into a heat exchanger for energy recovery. A corresponding filtering device or heat exchanger device is then likewise an integral part of the proposed arrangement.

It may furthermore be provided for the means for supplying an air flow and/or the treatment temperature maintaining zone to have control means for controlling the air flow or the temperature of the treatment temperature maintaining zone. This allows the drying process to ne controlled in a manner flexibly adaptable to various substrates and coatings, and thus the processing of different substrate/coating configurations for electrical or electronic applications in one and the same drying arrangement without complex constructional transformations.

Advantages and expediencies of the invention incidentally will arise from the following description of exemplary embodiments and aspects, in part on the basis of Figures. Shown are in:

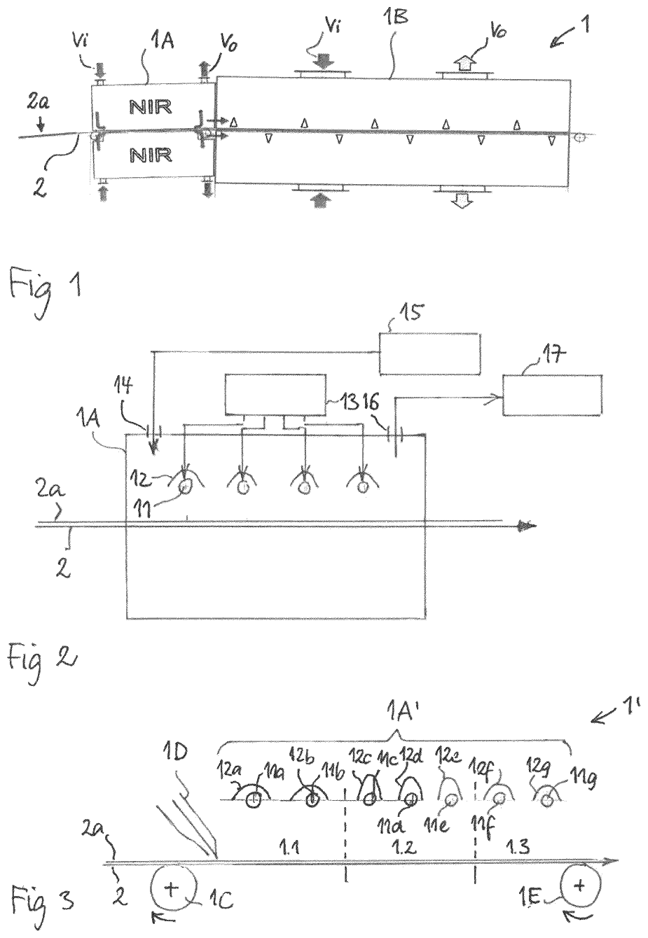

FIG. 1 a schematic representation of an embodiment of the arrangement according to the invention in the manner of a longitudinal section,

FIG. 2 a schematic representation of an embodiment of the NIR dryer 1A according to FIG. 1, and

FIG. 3 a schematic representation of a further embodiment of the NIR dryer of an arrangement according to the invention together with further plant components.

FIG. 1 shows the concept of a drying plant 1 for functionally coated substrates 2, which are intended to serve as battery or fuel cell electrodes in the finished state. The substrate may be a virtually endless Al film or Cu film, which have been coated in a coater (not shown here) by means of a blade system or a wide slot nozzle with a viscous paste 2a on the basis of water or based on an organic solvent having a typical solid content between 50% and 70%.

The thickness of the substrate film may be in the range between 5 and 150 μm, and the wet layer thickness of the viscous paste may be in the range between 10 and 1,000 μm. In the illustrated realization, the coating is applied on one side onto the surface of the substrate, however battery components coated on both sides may also be provided in consecutive coating and drying phases. Instead of metal films, polymer films (e.g. PET films) having a significantly larger thickness (e.g. between 100 and 150 μm) may be used as the substrates.

For drying the mentioned substrates, the drying plant 1 comprises a NIR dryer 1A having NIR radiators (not shown here) provided on both sides of the substrate 2, and an integrated hot air ventilation symbolized by the arrows Vi and Vo. The NIR dryer 1A has a variably settable temperature profile, which is realized by corresponding power controllers of the NIR dryers, and also the hot air flow is settable. In the conveying direction of the substrate 2 downstream of the NIR dryer 1A, a hot air dryer 1B connects directly to it, which likewise has a hot air ventilation Vi/Vo with a variably settable amount of air.

In a total plant length of several meters, which is considered to be advantageous for space reasons, and with a NIR dryer equipped with commercial NIR radiators having assigned reflectors, while considering the drying process quality requirements, throughput speeds in the range of 1-2 m/min, and thus a drying process may be realized, which offers significant advantages with respect to space requirements and throughput as compared to known drying plants.

FIG. 2 shows essential components of an exemplary NIR dryer 1A according to FIG. 1 by way of example in the manner of a functional block diagram. The Figure should be understood as a schematic sketch and is not intended to show the real mechanical construction of the NIR dryer. For the purpose of simplification, merely the functional components above the substrate 2 are represented. Corresponding components may also be provided below the substrate; but realizations of the arrangement according to the invention are also possible, in which corresponding means are exclusively provided on one (the coated) side of the substrate.

The NIR dryer 1A comprises several NIR radiators 11 each having an assigned reflector 12 and each being individually connected to one control output of a power control unit 13. The irradiation power of each individual NIR radiator 11 can thus be separately set via the power control unit 13, and thus a predetermined power density profile of the NIR radiation can be realized on the substrate 2 over the length of the NIR dryer 1A.

Via an air supply 14, an amount of air, which is controllable via an air amount control unit 15, gets into the input of the NIR dryer 1A, and via an exhaust air output 16, the heated exhaust air, which has adsorbed solvent components of the coating 2a, gets into a heat exchanging and filtering unit 17. In the heat exchanging and filtering unit 17, excessive heat is extracted from the exhaust air of the NIR dryer and provided for being externally used, and the solvent components are filtered out in an environmentally friendly manner and recycled, if necessary.

FIG. 3 shows an example of an arrangement 1′ for performing the method according to the invention, in which two transport rollers 1C, 1E as conveyance means for conveying the substrate 2 through the arrangement, and a blade device 1D as a coating device are schematically illustrated. For sintering/curing the coating 2a applied onto the substrate 2, a NIR irradiation zone 1A′ is realized by a plurality of NIR radiators 11a-11g each having a reflector 12a-12g fitted.

It is pointed out that the number and realization of the NIR radiators should be merely understood here as being a conceptual representation. By a set of radiators of different reflector geometry at a different distance, a pre-warming zone 1.1, a main drying zone 1.2 and a temperature maintaining zone 1.3 are realized within the NIR irradiation zone 1A′. This represents an alternative to the individual power setting explained further above in the context of FIG. 2 of NIR radiators that are basically of identical construction.

In an arrangement according to the invention, preponderantly cost-effective rod-shaped halogen spotlights, which have proven to be successful in drying tasks for a long time, come into question as the NIR radiators. Basically, however, a NIR irradiation zone may also be realized by radiators shaped otherwise or by an LED array having correspondingly high-power IR LEDs. Both realizations are familiar to the expert and therefore do not need any further explanation here.

As the reflectors, both individual reflectors, each structurally combined with a radiator, and integrated reflector arrangements come into question, which are assigned to several radiators. Also in such coherent reflector assemblies, different reflector geometries for the respective radiators can be realized (as shown in FIG. 3 in the manner of a sketch).

Arrangements of the kinds shown in the Figures, if necessary, modified in an application-specific way, are also usable for producing products from the field of “printed electronics”. The substrates are in this case, for example, paper or plastic films, which are not allowed to be heated above limit temperature in a range between approximately 80° C. and 140° C. depending on the material characteristics, and the substrates—depending on the function of the corresponding component—may be conductive inks, pastes or else powder. The thermal treatment consequently is targeted to evaporating water or solvents, sintering the paste, melting and, if necessary, sintering a powder, and, if necessary, also to inducing thermochemical reactions and phase transformations in the coating.

According to the inventors' researches, in these processes as well, the use of a NIR irradiation zone offers substantial acceleration and thus the possibility of significantly increasing the throughput and/or reducing the constructional length of a corresponding dryer.

The realization is not restricted to the examples and emphasized aspects explained above, but is likewise possible in a plurality of modifications, which are within the scope of the field of the attached claims.

1. A method for producing electrical or electronic components or circuits on a flexible, flat or three-dimensional substrate via the application of a liquid or paste-like starting material for a structured or unstructured electrical or electronic functional layer, and subsequent drying, sintering and/or curing the starting material on the substrate,
wherein the step of drying, sintering and/or curing involves a short surface-application of the coated substrate with radiation of halogen spotlights or IR LEDs in the near-infrared range, with an amplitude maximum in a wavelength range between 800 and 1,500 nm and with a power density on the surface of the substrate between 50 kW/m² and 1,000 kW/m².

2. The method according to claim 1, wherein the substrate is a temperature-sensitive substrate, such as a polymer film or paper, and the power density and the exposure time of the near-infrared radiation are set such that the temperature does not rise above a material-critical temperature, in particular not above a temperature in the range between 100° C. and 200° C.

3. The method according to claim 1, wherein liquid starting material is selectively applied to the substrate by a printing process, and the power density and exposure time of the near-infrared radiation are set such that within the selective coating, a temperature above a material-specific sintering or curing temperature, in particular above a temperature in the range between 50 and 200° C. is achieved for a short time.

4. The method according to claim 1, wherein a paste-like starting material is applied onto the substrate over the whole surface, in particular by a roller or blade application process, and the power density and exposure time of the near-infrared radiation are set such that within the selective coating, a temperature above a material-specific sintering or curing temperature is achieved for a short time.

5. The method according to claim 2, wherein the exposure time of the near-infrared radiation is chosen to be in the range between 1 s and 30 s, in particular between 2 s and 20 s.

6. The method according to claim 1, wherein the near-infrared radiation is performed within a NIR irradiation zone at a predetermined profile of non-constant power density, and the power density profile in the irradiation zone, in particular, is settable in response to material characteristics of the substrate and/or the starting material.

7. The method according to claim 1, wherein the near-infrared radiation is linked to an air flow at least on one surface of the substrate.

8. The method according to claim 7, wherein the air flow in the irradiation zone and/or a supply of hot air in an optionally provided hot air dryer onto both of the surfaces of the substrate is provided and is in particular settable.

9. The method according to claim 1, wherein subsequent to the near-infrared radiation, the coated substrate is conveyed through a treatment temperature maintaining zone, in particular a hot air dryer.

10. The method according to claim 1, configured as a method for producing a battery electrode or fuel cell electrode, wherein as the substrate, a polymer film having a thickness in the range between 75 μm and 200 μm or a metal film in the range between 3 μm and 10 μm, and as the coating, a viscous paste on the basis of water or based on an organic solvent is used, which has an initial thickness in the range between 10 and 1,000 μm and a solid content in the range between 40% and 80%, and wherein for the drying, sintering and/or curing, near-infrared radiation having a power density in the range between 50 and 200 kW/m², in particular 70 and 150 kW/m² is used.

11. An arrangement for performing the method according to claim 1, comprising
conveyance means for conveying the flexible substrate through the arrangement,
coating means for coating the flat substrate with the starting material, in particular during conveyance of the substrate, and
means for drying, sintering and/or curing the starting material layer on the substrate, in particular during conveyance of the substrate, which include at least one halogen spotlight or an IR LED for radiation in the range of near infrared, the amplitude maximum of which is in the wavelength range between 800 nm and 1,500 nm, and which is settable such that its power density on the surface of the substrate is in the range between 50 kW/m² and 1,000 kW/m².

12. The arrangement according to claim 11, wherein the means for drying, sintering and/or curing include a plurality of NIR radiation sources, which are arranged and/or controllable in a NIR irradiation zone such that, within the irradiation zone, a predetermined profile of non-constant power density is producible on the surface of the starting material layer.

13. The arrangement according to claim 11, wherein the means for drying, sintering and/or curing furthermore have a treatment temperature maintaining zone, which is in particular configured as a hot air dryer.

14. The arrangement according to claim 12, wherein the NIR irradiation zone has means assigned for supplying an air flow.

15. The arrangement according to claim 14, wherein the means for supplying an air flow and/or the treatment temperature maintaining zone have control means for controlling the air flow or the temperature in the treatment temperature maintaining zone.
